(19) United States
(12) Patent Application Publication
(10) Pub. No.: US 2022/0240418 A1
(43) Pub. Date: Jul. 28, 2022

(54) THERMAL CONDUCTIVE STRUCTURE AND ELECTRONIC DEVICE

(71) Applicant: CTRON Advanced Material Co., Ltd, Xinxiang City (CN)

(72) Inventors: MING-HSIANG HE, Xinxiang City (CN); CHUN-KAI HUANG, Xinxiang City (CN); HAN-CHANG HUANG, Xinxiang City (CN)

(21) Appl. No.: 17/541,595

(22) Filed: Dec. 3, 2021

(30) Foreign Application Priority Data
Jan. 27, 2021 (TW) 110103095

(51) Int. Cl. H05K 7/20

(52) U.S. Cl. CPC H05K 7/20509; H05K 7/20409

(57) ABSTRACT

A thermal conductive structure and an electronic device are provided. The thermal conductive structure includes a thermal conductive metal layer, a first carbon nanotube layer, a first thermal conductive adhesive layer, and a ceramic protective layer. The first carbon nanotube layer is disposed on a first surface of the thermal conductive metal layer and includes a plurality of first carbon nanotubes. The first thermal conductive adhesive layer is disposed at the first carbon nanotube layer, wherein the material of the first thermal conductive adhesive layer fills in the gaps of the first carbon nanotubes. The ceramic protective layer is disposed at one side of the first carbon nanotube layer away from the thermal conductive metal layer. The thermal conductive structure can quickly conduct the heat generated by the heat source to the outside, and improve the heat dissipation performance of the electronic device.

### CROSS REFERENCE TO RELATED APPLICATIONS

This Non-provisional application claims priority under 35 U.S.C. § 119(a) on Patent Application No(s). 110103095 filed in Taiwan, Republic of China on Jan. 27, 2021, the entire contents of which are hereby incorporated by reference.

### BACKGROUND

### Technology Field

The present disclosure relates to a thermal conductive structure and, in particular, to a thermal conductive structure and an electronic device capable of improving heat dissipation performance.

### Description of Related Art

With the development of technology, the thin structure and high performance are the priority considerations for the design and development of electronic devices. Under the high-speed operation and thin structure requirements, the electronic components of electronic device will inevitably generate more heat than ever. Therefore, the “heat dissipation” has become an indispensable function of these components or devices. Especially for high-power components, the temperature of electronic products will rise rapidly due to the substantial increase in heat generated during operation. When the electronic product is exposed to an excessive temperature, it may cause permanent damage to the components or significantly reduce the lifetime thereof.

In most of the conventional arts, the waste heat generated in operation is dissipated by the heat sink, fan, or heat-dissipation element (e.g. heat pipe) installed on the components or devices. In general, the heat sink or the heat-dissipation element generally has a certain thickness, and is made of metal material with high thermal conductivity, or a material doped with an inorganic material with high thermal conductivity. Although the thermal conduction effect of the metal material is very good, but the density thereof is large, resulting in the heavy weight and large thickness of the entire heat sink or heat-dissipation element. In addition, the structural strength of a polymer composite doped with the inorganic material is not good and may not be suitable for some products.

Therefore, it is desired to provide a thermal conductive structure, which is more suitable for high-power component or device, and can be applied to different product fields to meet the requirement of thin design.

### SUMMARY

An objective of this disclosure is to provide a thermal conductive structure and an electronic device with the thermal conductive structure. The thermal conductive structure of this disclosure can rapidly conduct the heat energy generated by the heat source of the electronic device to the outside, thereby improving the heat dissipation performance.

The thermal conductive structure of this disclosure can be applied to different product fields to meet the requirement of thin design.

A thermal conductive structure of this disclosure comprises a thermal conductive metal layer, a first carbon nanotube layer, a first thermal conductive adhesive layer, and a ceramic protective layer. The thermal conductive metal layer has a first surface and a second surface opposite to the first surface. The first carbon nanotube layer is disposed on the first surface of the thermal conductive metal layer and comprises a plurality of first carbon nanotubes. The first thermal conductive adhesive layer is disposed at the first carbon nanotube layer, wherein the material of the first thermal conductive adhesive layer fills in gaps of the first carbon nanotubes. The ceramic protective layer is disposed at one side of the first carbon nanotube layer away from the thermal conductive metal layer.

In one embodiment, the thermal conductive metal layer comprises copper, aluminum, copper alloy, or aluminum alloy.

In one embodiment, the first thermal conductive adhesive layer fully fills the gaps between the first carbon nanotubes.

In one embodiment, the first thermal conductive adhesive layer further fully fills the gaps inside the first carbon nanotubes.

In one embodiment, the material of the ceramic protective layer comprises boron nitride, aluminum oxide, aluminum nitride, silicon carbide, or any combination thereof

In one embodiment, the material of the ceramic protective layer further comprises graphene.

In one embodiment, the thermal conductive structure further comprises a second carbon nanotube layer and a second thermal conductive adhesive layer. The second carbon nanotube layer is disposed on the second surface of the thermal conductive metal layer and comprises a plurality of second carbon nanotubes. The second thermal conductive adhesive layer is disposed at the second carbon nanotube layer, wherein the material of the second thermal conductive adhesive layer fills in gaps of the second carbon nanotubes.

In one embodiment, an included angle between the thermal conductive metal layer and an axial direction of the first carbon nanotubes or the second carbon nanotubes is greater than 0 and is less than or equal to 90 degrees.

In one embodiment, the second thermal conductive adhesive layer fully fills the gaps between the second carbon nanotubes.

In one embodiment, the second thermal conductive adhesive layer further fully fills the gaps inside the second carbon nanotubes.

In one embodiment, the first thermal conductive adhesive layer or the second thermal conductive adhesive layer comprises an adhesive material and a thermal conductive material, and the thermal conductive material comprises graphene, reduced graphene oxide, or ceramic material.

In one embodiment, a surface of the ceramic protective layer away from the thermal conductive metal layer is configured with a plurality of microstructures, and a shape of the microstructures is columnar, spherical, pyramidal, trapezoidal, irregular shape, or any combination thereof

In one embodiment, the ceramic protective layer further comprises a filling material and/or a plurality of pores.

In one embodiment, the filling material comprises aluminum oxide, aluminum nitride, silicon carbide, boron nitride, or any combination thereof

In one embodiment, a shape of the filling material comprises granular, flake, spherical, strip, nanotube, irregular, or any combination thereof

In one embodiment, the thermal conductive structure further comprises a double-sided adhesive layer, which is disposed at one side of the second surface of the thermal conductive metal layer away from the ceramic protective layer.

In one embodiment, the double-sided adhesive layer is a thermal conductive double-sided tape.

An electronic device of this disclosure comprises a heat source and the above-mentioned thermal conductive structure connected to the heat source.

In one embodiment, the electronic device further comprises a heat-dissipation structure disposed at one side of the thermal conductive structure away from the heat source.

In one embodiment, the thermal conductive structure further comprises a double-sided adhesive layer, which is disposed at one side of the second surface of the thermal conductive metal layer away from the ceramic protective layer.

As mentioned above, in the thermal conductive structure of this disclosure, the first carbon nanotube layer is disposed at the thermal conductive metal layer, wherein the material of the thermal conductive metal layer fills in the gaps of the first carbon nanotubes of the first carbon nanotube layer. In addition, the ceramic protective layer is disposed at one side of the first carbon nanotube layer away from the thermal conductive metal layer. When the thermal conductive structure is connected to the heat source of the electronic device, the heat energy generated by the heat source can be rapidly and effectively conducted to the outside, thereby improving the heat dissipation performance of the electronic device. Besides, compared with the conventional protective layer, the ceramic protective layer of this disclosure can provide the protection and insulation effects, and can further improve the thermal conductive effect. Moreover, the thermal conductive structure of this disclosure can be applied to different product fields, thereby achieving the requirement of thin design of the electronic device.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing a thermal conductive structure according to an embodiment of this disclosure;

FIGS. 2A to 2F are schematic diagrams showing the thermal conductive structures according to different embodiments of this disclosure; and

FIGS. 3 and 4 are schematic diagrams showing the electronic devices according to different embodiments of this disclosure.

### DETAILED DESCRIPTION OF THE DISCLOSURE

The present disclosure will be apparent from the following detailed description, which proceeds with reference to the accompanying drawings, wherein the same references relate to the same elements. The elements appearing in the following embodiments are only used to illustrate the relative relationships thereof, and do not represent the real proportions or sizes thereof

When the thermal conductive structure of the present disclosure is applied to an electronic device, the heat dissipation efficiency of the electronic device can be improved. The heat source of the electronic device can be a battery, a control chip (e.g. CPU), a memory (e.g. for example but not limited to SSD), a motherboard, a display card, a display panel, a flat light source of the electronic device, or any of other components, units, or modules, and this disclosure is not limited. In addition, the thermal conductive structure of the present disclosure can be applied to different product fields to meet the requirements of thin design.

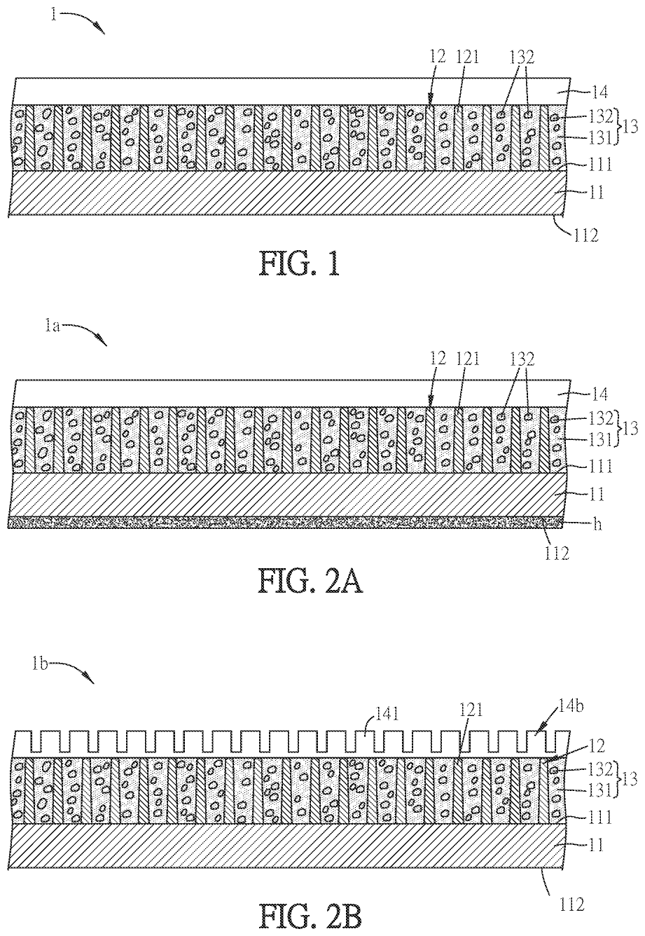

FIG. 1 is a schematic diagram showing a thermal conductive structure according to an embodiment of this disclosure. As shown in FIG. 1, the thermal conductive structure 1 of this embodiment comprises a thermal conductive metal layer 11, a first carbon nanotube layer 12, a first thermal conductive adhesive layer 13, and a ceramic protective layer 14.

The thermal conductive metal layer 11 has a first surface 111 and a second surface 112, and the second surface 112 is disposed opposite to the first surface 111. Herein, the thermal conductive metal layer 11 comprises a material with high thermal conductive coefficient such as a metal plate, a metal foil, or a metal film, and the material thereof can be, for example but not limited to, copper, aluminum, copper alloy (an alloy containing copper and other metals), or aluminum alloy (an alloy containing aluminum and other metals), or a combination thereof. In this embodiment, for example, the thermal conductive metal layer 11 is an aluminum foil.

The first carbon nanotube layer 12 is disposed on the first surface 111 of the thermal conductive metal layer 11. The first carbon nanotube layer 12 comprises a plurality of first carbon nanotubes 121. The included angle between the thermal conductive metal layer 11 and the axial direction of the first carbon nanotubes 121 is greater than 0 and is less than or equal to 90 degrees. This configuration can increase the thermal conductive effect of the thermal conductive metal layer 11 in the vertical direction. For example, the axial direction of the first carbon nanotubes 121 is perpendicular to the first surface 111 of the thermal conductive metal layer 11. In some embodiments, the axial direction of the first carbon nanotubes 121 can be perpendicular to or approximately perpendicular to the first surface 111 of the thermal conductive metal layer 11. In addition, the included angle between the thermal conductive metal layer 11 and the axial direction of the first carbon nanotubes 121 can be between 0 and 90 degrees, and this disclosure is not limited thereto.

The first thermal conductive adhesive layer 13 is disposed at the first carbon nanotube layer 12, wherein the material of the first thermal conductive adhesive layer 13 fills in gaps of the first carbon nanotubes 121 of the first carbon nanotube layer 12. Specifically, the first thermal conductive adhesive layer 13 can be made of a material with fluidity such as a gel or a paste, and the material can be disposed on the first carbon nanotube layer 12 by jet coating, printing or any of other suitable methods. After the material of the first thermal conductive adhesive layer 13 flows and fills in the gaps of the first carbon nanotubes 121 (preferably fully fills in the gaps), the first thermal conductive adhesive layer 13 can be formed accordingly. The first carbon nanotubes 121 have extremely high thermal conductivity (>3000 W/m-K). Moreover, when the material of the first thermal conductive adhesive layer 13 fills in the gaps of the first carbon nanotubes 121, the thermal conductive effect can be further improved. In some embodiments, in addition to fill the gaps between the first carbon nanotubes 121, the first thermal conductive adhesive layer 13 can be filled or fully filled in the gaps inside the first carbon nanotubes 121. In some embodiments, the first thermal conductive adhesive layer 13 can be fully filled in the gaps between and inside the first carbon nanotubes 121, thereby achieving a better thermal conductive effect. In some embodiments, in addition to fully fill the gaps between and inside the first carbon nanotubes 121, the first thermal conductive adhesive layer 13 can further cover the surface of the first carbon nanotube layer 12 away from the thermal conductive metal layer 11. In other words, the first thermal conductive adhesive layer 13 covers the entire first carbon nanotube layer 12. Of course, due to the manufacturing process or other factors, the gaps between or inside the first carbon nanotubes 121 may not be completely filled by the material of the first thermally conductive adhesive layer 13.

The first thermal conductive adhesive layer 13 can be made of a thermal conductive adhesive, which comprises an adhesive material 131 and a thermal conductive material 132. The thermal conductive material 132 is mixed in the adhesive material 131. The adhesive material 131 of the first thermal conductive adhesive layer 13 can not only increase the structural strength of the first carbon nanotube layer 12, but also further improve the thermal conductive effect in the vertical direction by mixing the thermal conductive material 132 is mixed in the adhesive material 131. The above-mentioned thermal conductive material 132 comprises, for example, graphene, reduced graphene oxide, or ceramic material, or any combination thereof. The ceramic material can be a ceramic material with high thermal conductive coefficient (K) such as, for example but not limited to, boron nitride (BN), aluminum oxide (Al₂O₃), aluminum nitride (AlN), silicon carbide (SiC), or any combination thereof, and this disclosure is not limited.

In this embodiment, the thermal conductive material 132 is, for example, graphene microchips. In some embodiments, the content of graphene microchips in the entire first thermal conductive adhesive layer 13 can be greater than 0 and be less than or equal to 15% (0<the content of graphene microchips<15%), such as 1.5%, 3.2%, 5%, 7.5%, 11%, 13%, or the like. In addition, the above-mentioned adhesive material 131 can be, for example but not limited to, a pressure sensitive adhesive (PSA), which is made of, for example, rubber, acrylic, or silicone, or a combination thereof The chemical composition thereof can be rubber, acrylic, or silicone, or a combination thereof, and the disclosure is not limited.

The ceramic protective layer 14 is disposed at one side of the first carbon nanotube layer 12 away from the thermal conductive metal layer 11. In this embodiment, the ceramic protective layer 14 is disposed on and directly connected to the upper surface of the first carbon nanotube layer 12 away from the first surface 11 of the thermal conductive metal layer 11. In some embodiments, the ceramic protective layer 14 can be formed on the first carbon nanotube layer 12 and/or the first thermal conductive adhesive layer 13 by jet coating, printing, or the like. The material of the ceramic protective layer 14 can comprise, for example but not limited to, an adhesive material and a ceramic material with high thermal conductive coefficient, and the ceramic material is mixed in the adhesive material. The ceramic material can be, for example, boron nitride (BN), aluminum oxide (Al₂O₃), aluminum nitride (A1N), silicon carbide (SiC), or any combination thereof, or any of other ceramic material with high thermal conductive coefficient. In some embodiments, in addition to the above-mentioned materials, the ceramic protective layer 14 can further comprise graphene. In this embodiment, the mixing ratio of graphene and the ceramic material can be, for example, 1:9, 3:7, 5:5, or any other ratios, and this disclosure is not limited. In this embodiment, the material of the ceramic protective layer 14 comprises boron nitride (BN) for example. To be noted, the first carbon nanotubes 121 of the first carbon nanotube layer 12 and the graphene (the thermal conductive material 132) of the first thermal conductive adhesive layer 13 have the electronic conductivity. Accordingly, compared with the conventional protective layer, which is made of polyimide (PI), the ceramic protective layer 14 can not only provide the protection (wearing durability) and insulation properties, but also have a thermal conductive function. In other embodiments, the ceramic protective layer 14 can be attached to the upper surface of the first carbon nanotube layer 12 by, for example, a thermal conductive adhesive.

As mentioned above, in the thermal conductive structure 1 of this embodiment, the first carbon nanotube layer 12 is disposed at the thermal conductive metal layer 11, wherein the material of the first thermal conductive metal layer 13 fills in the gaps of the first carbon nanotubes 121 of the first carbon nanotube layer 12. In addition, the ceramic protective layer 14 is disposed at one side of the first carbon nanotube layer 12 away from the thermal conductive metal layer 11. When the thermal conductive structure 1 is connected to the heat source of the electronic device, the heat energy generated by the heat source can be rapidly and effectively conducted to the outside, thereby improving the heat dissipation performance of the electronic device. Besides, compared with the conventional protective layer, the ceramic protective layer 14 of this embodiment can provide the protection (wearing durability) and insulation effects, and can further improve the thermal conductive effect. Moreover, the thermal conductive structure 1 of this embodiment can be applied to different product fields, thereby achieving the requirement of thin design of the electronic device.

In some embodiments, the thermal conductive structure can further comprise two release layers (not shown), which are disposed at two opposite sides of the thermal conductive structure (e.g. the upper side and the lower side of the thermal conductive structure 1 as shown in FIG. 1). Upon using the thermal conductive structure, the user can merely remove the two release layers so as to attach the thermal conductive structure to the heat source through the double-sided tape (e.g. a thermal conductive double-sided tape). The material of the thermal conductive double-sided tape can be, for example, the same as that of the first thermal conductive metal layer 13, which can provide the adhesion function and assist to conduct the heat energy. In addition, the material of the release layers can be, for example but not limited to, paper, cloth, polyester (e.g. polyethylene terephthalate, PET), or a combination thereof. To be noted, the aspect that the upper and lower sides of the thermal conductive structure are configured with corresponding release layers can also be applied to all the following embodiments of the present disclosure.

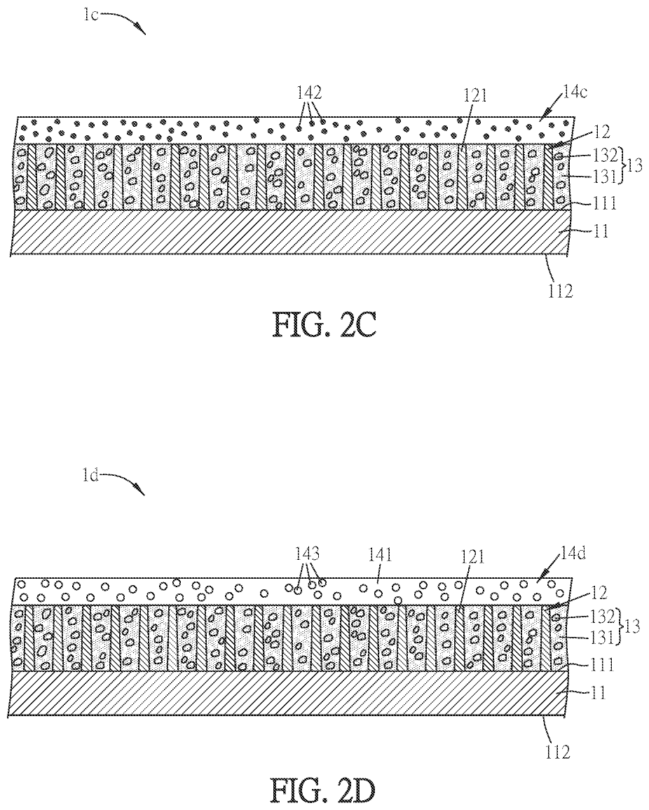

FIGS. 2A to 2F are schematic diagrams showing the thermal conductive structures according to different embodiments of this disclosure.

The configurations and connections of the components in the thermal conductive structure 1a of this embodiment as shown in FIG. 2A are mostly the same as those of the thermal conductive structure 1 of the above-mentioned embodiment. Different from the above embodiment, the thermal conductive structure 1a of this embodiment further comprises a double-sided adhesive layer h disposed at one side of the second surface 112 of the thermal conductive metal layer 11 away from the ceramic protective layer 14. In this embodiment, the double-sided adhesive layer h is disposed on the second surface 112 of the thermal conductive metal layer 11. Since the double-sided adhesive layer h is disposed between the thermal conductive metal layer 11 and the heat source, the thermal conductive structure 1a can be attached to the heat source through the double-sided adhesive layer h, thereby rapidly conducting and dissipating the heat energy generated by the heat source to the outside through the thermal conductive structure 1a. Of course, one side of the ceramic protective layer 14 away from the heat source can also be configured with a heat dissipation structure (not shown) for speeding the heat dissipation. In addition, the feature of utilizing the double-sided adhesive layer h to connect the thermal conductive structure and the heat source can also be applied to the thermal conductive structures of the following embodiments.

In addition, the configurations and connections of the components in the thermal conductive structure 1b of this embodiment as shown in FIG. 2B are mostly the same as those of the thermal conductive structure 1 of the above-mentioned embodiment. Different from the above embodiment, a surface of the ceramic protective layer 14b of the thermal conductive structure 1b of this embodiment away from the thermal conductive metal layer 11 is configured with a plurality of microstructures 141, and the shape of the microstructures can be, for example, columnar, spherical, pyramidal, trapezoidal, irregular shape, or any combination thereof. This disclosure is not limited thereto. In some embodiments, the microstructures 141 can be fabricated on the surface of the ceramic protective layer 14b by, for example, screen printing, embossing printing, or other methods, so as to increase the heat dissipation area. This configuration can enhance the heat dissipation effect. The feature of forming a plurality of microstructures 141 on the surface of the ceramic protective layer 14b can also be applied to other embodiments of this disclosure.

In addition, the configurations and connections of the components in the thermal conductive structure 1c of this embodiment as shown in FIG. 2C are mostly the same as those of the thermal conductive structure 1 of the above-mentioned embodiment. Different from the above embodiment, the ceramic protective layer 14c of the thermal conductive structure 1c further comprises a filling material 142. The filling material 142 can be, for example, a ceramic material, and the shape thereof can be granular, flake, spherical, strip, nanotube, irregular, or any combination thereof, and this disclosure is not limited. Moreover, the particle size of the filling material 142 is between 0.5 μm and 10 μm. In some embodiments, the filling material 142 comprises, for example, aluminum oxide, aluminum nitride, silicon carbide, boron nitride, or any combination thereof. The configuration of the filling material 142 can increase the heat dissipation effect of the ceramic protective layer 14c. The filling material 142 having a nanotube shape can be a boron nitride nanotube.

In addition, the configurations and connections of the components in the thermal conductive structure 1d of this embodiment as shown in FIG. 2D are mostly the same as those of the thermal conductive structure 1 of the above-mentioned embodiment. Different from the above embodiment, the ceramic protective layer 14d of the thermal conductive structure 1d further comprises a plurality of pores 143. In some embodiments, a pore forming agent can be added in the manufacturing process of the ceramic protective layer 14d, so that the ceramic protective layer 14d can be formed with a plurality of pores 143 to increase the specific surface area and thus enhance the heat-radiation heat dissipation effect. In some embodiments, the pore forming agent is, for example, a ceramic pore forming agent.

In addition, the configurations and connections of the components in the thermal conductive structure 1e of this embodiment as shown in FIG. 2E are mostly the same as those of the thermal conductive structure 1 of the above-mentioned embodiment. Different from the above embodiment, the ceramic protective layer 14e of the thermal conductive structure 1e comprises a filling material 142 and a plurality of pores 143. The feature of the ceramic protective layer 14e, which is added with the filling material 142 and/or the pore forming agent to form a plurality of pores 143, can also be applied to other embodiments of this disclosure.

In addition, the configurations and connections of the components in the thermal conductive structure 1f of this embodiment as shown in FIG. 2F are mostly the same as those of the thermal conductive structure 1 of the above-mentioned embodiment. Different from the above embodiment, the thermal conductive structure if of this embodiment further comprises a second carbon nanotube layer 12a and a second thermal conductive adhesive layer 13a. The second carbon nanotube layer 12a is disposed on the second surface 112 of the thermal conductive metal layer 11 and comprises a plurality of second carbon nanotubes 121. The second thermal conductive adhesive layer 13a is disposed at the second carbon nanotube layer 12a, wherein a material of the second thermal conductive adhesive layer 12a fills in gaps of the second carbon nanotubes 121 (preferably, fully fills all gaps). In some embodiments, in addition to filling the gaps between the second carbon nanotubes 121, and the material of the second thermal conductive adhesive layer 13a further fills (or fully fills) the gaps inside the second carbon nanotubes 121. In some embodiments, the material of the second thermal conductive adhesive layer 13a fully fills the gaps between and inside the second carbon nanotubes 121, thereby achieving a better thermal conductive effect. In this embodiment, the included angle between the thermal conductive metal layer 11 and the axial direction of the second carbon nanotubes 121 is greater than 0 and is less than or equal to 90 degrees. Accordingly, the thermal conductive structure if can have a better thermal conductive effect. The material of the second thermal conductive adhesive layer 13a can be the same as or different from that of the first thermal conductive adhesive layer 13, and this disclosure is not limited. The feature that the thermal conductive structure comprises the second thermal conductive adhesive layer 12a and the second thermal conductive adhesive layer 13a can also be applied to other embodiments of this disclosure.

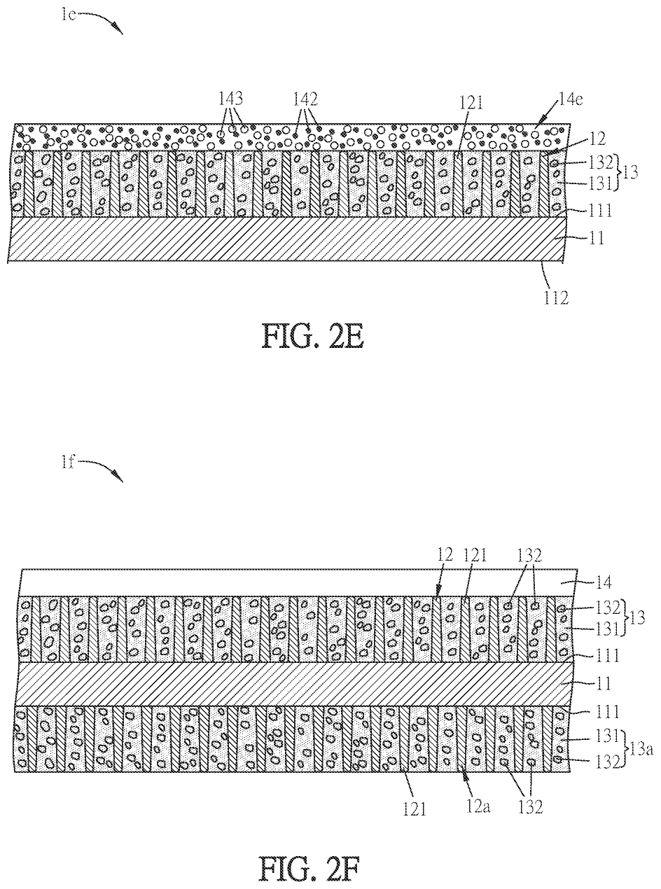

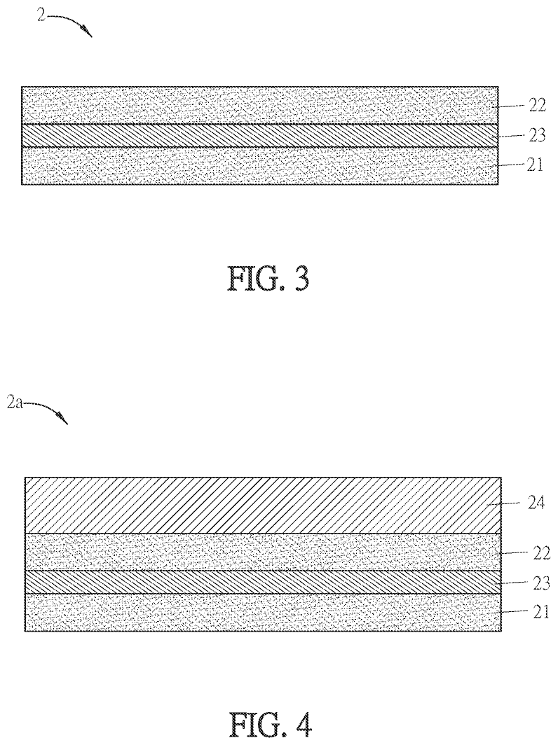

FIGS. 3 and 4 are schematic diagrams showing the electronic devices according to different embodiments of this disclosure. As shown in FIG. 3, this disclosure further provides an electronic device 2, which comprises a heat source 21 and a thermal conductive structure 22. The thermal conductive structure 22 is connected to the heat source 21. In some embodiments, the thermal conductive structure 22 is connected to the heat source 21 through a double-sided adhesive layer 23, such as a thermal conductive double-sided tape. In this embodiment, the thermal conductive structure 22 can be any of the above mentioned thermal conductive structure 1 and 1a to lf, or their modifications. The specific technical content thereof can be referred to the above embodiments, so the detailed descriptions thereof will be omitted. To be understood, if the thermal conductive structure 22 further comprises the above-mentioned double-sided adhesive layer h, the double-sided adhesive layer 23 is not needed.

The electronic device 2 or 2a can be, for example but not limited to, a flat display device or a flat light source, such as, for example but not limited to, a mobile phone, a laptop computer, a tablet computer, a TV, a display device, a backlight module, or a lighting module, or any of other flat electronic devices. The heat source can be a battery, a control chip (e.g. CPU), a memory (e.g. for example but not limited to SSD), a motherboard, a display card, a display panel, a flat light source of the electronic device, or any of other components or units capable of generating heat, and this disclosure is not limited. In some embodiments, when the electronic device 2 is a flat display device, such as, for example but not limited to, an LED display device, an OLED display device, or an LCD, the heat source 21 can be a display panel with a display surface, and the thermal conductive structure 22 can be directly or indirectly (e.g. through a thermal conductive double-sided tape) attached to the opposite surface of the display surface, thereby assisting the heat conduction and heat dissipation, and thus improving the heat dissipation performance of the flat display device. In other embodiments, when the electronic device 2 is a flat light source, such as, for example but not limited to, a backlight module, an LED lighting module, or an OLED lighting module, the heat source 21 can be a light-emitting unit with a light outputting surface. The thermal conductive structure 22 can be directly or indirectly (e.g. through the adhesive) attached to the opposite surface of the light outputting surface, thereby assisting the heat conduction and heat dissipation, and thus improving the heat dissipation performance of the flat light source.

In addition, as shown in FIG. 4, the electronic device 2a of this embodiment further comprises a heat dissipation structure 24, which is disposed at one side of the thermal conductive structure 22 away from the heat source 21. Accordingly, in the electronic device 2a, the heat dissipation structure 24 can be connected to the heat source 21 through the thermal conductive structure 22, so that the heat energy generated by the heat source 21 can be rapidly transmitted to the heat dissipation structure 24 through the thermal conductive structure 22. Then, the heat energy generated by the electronic device 2a can be dissipated to the outside through the heat dissipation structure 24, thereby improving the heat dissipation effect. In some embodiments, the heat dissipation structure 24 can be, for example, a heat-dissipation film such as, for example but not limited to, a graphene thermal film (GTF). In addition, the heat dissipation structure 24 can be any conventional heat dissipation device or structure such as the fan, fins, heat dissipation paste, heat-dissipation plate, heat sink, . . . , or any of other types of heat dissipation elements, heat dissipation units or heat dissipation devices, or combinations thereof, and this disclosure is not limited. In some embodiments, the heat dissipation structure 24 and the thermal conductive structure 22 can be connected through, for example, a thermal conductive double-sided tape.

In summary, in the thermal conductive structure of this disclosure, the first carbon nanotube layer is disposed at the thermal conductive metal layer, wherein the material of the thermal conductive metal layer fills in the gaps of the first carbon nanotubes of the first carbon nanotube layer. In addition, the ceramic protective layer is disposed at one side of the first carbon nanotube layer away from the thermal conductive metal layer. When the thermal conductive structure is connected to the heat source of the electronic device, the heat energy generated by the heat source can be rapidly and effectively conducted to the outside, thereby improving the heat dissipation performance of the electronic device. Besides, compared with the conventional protective layer, the ceramic protective layer of this disclosure can provide the protection and insulation effects, and can further improve the thermal conductive effect. Moreover, the thermal conductive structure of this disclosure can be applied to different product fields, thereby achieving the requirement of thin design of the electronic device.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A thermal conductive structure, comprising:
a thermal conductive metal layer having a first surface and a second surface opposite to the first surface;
a first carbon nanotube layer disposed on the first surface of the thermal conductive metal layer and comprising a plurality of first carbon nanotubes;
a first thermal conductive adhesive layer disposed at the first carbon nanotube layer, wherein a material of the first thermal conductive adhesive layer fills in gaps of the first carbon nanotubes; and
a ceramic protective layer disposed at one side of the first carbon nanotube layer away from the thermal conductive metal layer.

2. The thermal conductive structure of claim 1, wherein the thermal conductive metal layer comprises copper, aluminum, copper alloy, or aluminum alloy.

3. The thermal conductive structure of claim 1, wherein the first thermal conductive adhesive layer fully fills the gaps between the first carbon nanotubes.

4. The thermal conductive structure of claim 3, wherein the first thermal conductive adhesive layer further fully fills the gaps inside the first carbon nanotubes.

5. The thermal conductive structure of claim 1, wherein a material of the ceramic protective layer comprises boron nitride, aluminum oxide, aluminum nitride, silicon carbide, or any combination thereof

6. The thermal conductive structure of claim 5, wherein the material of the ceramic protective layer further comprises graphene.

7. The thermal conductive structure of claim 1, further comprising:
a second carbon nanotube layer disposed on the second surface of the thermal conductive metal layer and comprising a plurality of second carbon nanotubes; and
a second thermal conductive adhesive layer disposed at the second carbon nanotube layer, wherein a material of the second thermal conductive adhesive layer fills in gaps of the second carbon nanotubes.

8. The thermal conductive structure of claim 7, wherein an included angle between the thermal conductive metal layer and an axial direction of the first carbon nanotubes or the second carbon nanotubes is greater than 0 and is less than or equal to 90 degrees.

9. The thermal conductive structure of claim 7, wherein the second thermal conductive adhesive layer fully fills the gaps between the second carbon nanotubes.

10. The thermal conductive structure of claim 9, wherein the second thermal conductive adhesive layer further fully fills the gaps inside the second carbon nanotubes.

11. The thermal conductive structure of claim 7, wherein the first thermal conductive adhesive layer or the second thermal conductive adhesive layer comprises an adhesive material and a thermal conductive material, and the thermal conductive material comprises graphene, reduced graphene oxide, or ceramic material.

12. The thermal conductive structure of claim 1, wherein a surface of the ceramic protective layer away from the thermal conductive metal layer is configured with a plurality of microstructures, and a shape of the microstructures is columnar, spherical, pyramidal, trapezoidal, irregular shape, or any combination thereof

13. The thermal conductive structure of claim 1, wherein the ceramic protective layer further comprises a filling material and/or a plurality of pores.

14. The thermal conductive structure of claim 13, wherein the filling material comprises aluminum oxide, aluminum nitride, silicon carbide, boron nitride, or any combination thereof

15. The thermal conductive structure of claim 13, wherein a shape of the filling material comprises granular, flake, spherical, strip, nanotube, irregular, or any combination thereof

16. The thermal conductive structure of claim 1, further comprising:
a double-sided adhesive layer disposed at one side of the second surface of the thermal conductive metal layer away from the ceramic protective layer.

17. The thermal conductive structure of claim 16, wherein the double-sided adhesive layer is a thermal conductive double-sided tape.

18. An electronic device, comprising:
a heat source; and
a thermal conductive structure of claim 1, wherein the thermal conductive structure is connected to the heat source.

19. The electronic device of claim 18, further comprising:
a heat-dissipation structure disposed at one side of the thermal conductive structure away from the heat source.

20. The electronic device of claim 18, wherein the thermal conductive structure further comprises:
a double-sided adhesive layer disposed at one side of the second surface of the thermal conductive metal layer away from the ceramic protective layer.
